(19) United States
(12) Patent Application Publication
(10) Pub. No.: US 2024/0420991 A1
(43) Pub. Date: Dec. 19, 2024

(54) SEMICONDUCTOR DEVICE WITH DEEP TRENCH ISOLATION AND SHALLOW TRENCH ISOLATION AND FABRICATING METHOD OF THE SAME

(71) Applicant: UNITED MICROELECTRONICS CORP., Hsin-chu City (TW)

(72) Inventors: Jing-Wen Huang, Pingtung County (TW); Chih-Yuan Wen, Tainan City (TW); Lung-En Kuo, Tainan City (TW); Po-Chang Lin, Tainan City (TW); Kun-Yuan Liao, Hsinchu City (TW); Chung-Yi Chiu, Tainan City (TW)

(73) Assignee: UNITED MICROELECTRONICS CORP., Hsin-chu City (TW)

(21) Appl. No.: 18/219,107

(22) Filed: Jul. 7, 2023

(30) Foreign Application Priority Data
Jun. 16, 2023 (TW) 112122516

(51) Int. Cl. H01L 21/762; H01L 27/088

(52) U.S. Cl. CPC H01L 21/76229; H01L 27/088

(57) ABSTRACT

A semiconductor device with a deep trench isolation and a shallow trench isolation includes a substrate. The substrate is divided into a high voltage transistor region and a low voltage transistor region. A deep trench is disposed within the high voltage transistor region. The deep trench includes a first trench and a second trench. The first trench includes a first bottom. The second trench extends from the first bottom toward a bottom of the substrate. A first shallow trench and a second shallow trench are disposed within the low voltage transistor region. A length of the first shallow trench is the same as a length of the second trench. An insulating layer fills in the first trench, the second trench, the first shallow trench and the second shallow trench.

### BACKGROUND OF THE INVENTION

### 1. Field of the Invention

The present invention relates to a manufacturing method of integrating deep trench insulation in a high voltage transistor region and a shallow trench insulation in a low voltage transistor region, and a semiconductor device with deep trench insulation and the shallow trench insulation formed by using the aforementioned manufacturing method.

### 2. Description of the Prior Art

In current semiconductor processing, controllers, memories, circuits of low-voltage operation and power devices of high-voltage operation are largely integrated into a single chip to achieve a single-chip system. The power device, such as vertical double-diffusion metal-oxide-semiconductor (VDMOS), insulated gate bipolar transistor (IGBT) and lateral diffusion MOS (LDMOS), is employed to increase power switching efficiency and decrease the loss of energy resources. It is often required that the switching transistors withstand high breakdown voltages and operate at a low on-resistance.

Moreover with the trend in the industry being towards scaling down the size of the metal oxide semiconductor transistors (MOS), three-dimensional or non-planar transistor technology, such as fin field effect transistor technology (FinFET) has been developed to replace planar MOS transistors. Since the three-dimensional structure of a FinFET increases the overlapping area between the gate and the fin-shaped structure of the silicon substrate, the channel region can therefore be more effectively controlled. This way, the drain-induced barrier lowering (DIBL) effect and the short channel effect are reduced. The channel region is also longer for an equivalent gate length, thus the current between the source and the drain is increased. In addition, the threshold voltage of the fin FET can be controlled by adjusting the work function of the gate.

However as the scale of current devices continue to decrease, the integration of high-voltage devices and FinFET devices start to face numerous challenges. Therefore, a new high voltage transistor structure with improved function is needed

### SUMMARY OF THE INVENTION

In view of this, an integrated fabricating method of forming a deep trench isolation in a high voltage transistor region and a shallow trench isolation in a low voltage transistor region to provide a deep trench isolation with enough depth within the high voltage transistor region.

According to a preferred embodiment of the present invention, a semiconductor device with a deep trench isolation and a shallow trench isolation includes a substrate divided into a high voltage transistor region and a low voltage transistor region. A pad silicon oxide and a pad silicon nitride cover the high voltage transistor region and the low voltage transistor region. A deep trench is disposed within the pad silicon nitride, the pad silicon oxide and the substrate within the high voltage region. The deep trench includes a first trench includes a first bottom. A second trench extends from the first bottom toward a bottom of the substrate. A first shallow trench and a second shallow trench are disposed in the pad silicon nitride, the pad silicon oxide and the substrate within the low voltage transistor region, wherein the first shallow trench and the second shallow trench define a fin structure on the substrate, a length of the first shallow trench is the same as a length of the second trench. An insulating layer fills in the first trench, the second trench, the first shallow trench and the second shallow trench.

According to another preferred embodiment of the present invention, an integrated fabricating method of a deep trench isolation in a high voltage transistor region and a shallow trench isolation in a low voltage transistor region includes providing a substrate includes a high voltage transistor region and a low voltage transistor region, a pad silicon nitride and a pad of silicon oxide covering the high voltage transistor region and the low voltage transistor region. Next, the pad silicon nitride, the pad silicon oxide and the substrate are etched to form a first trench in the pad silicon nitride, the pad silicon oxide and the substrate within the high voltage transistor region. Later, a patterned mask is formed to cover the high voltage transistor region and the low voltage transistor region, wherein the patterned mask fills the first trench, and a predetermined position of the second trench is defined in the patterned mask within the high voltage transistor region and a predetermined position of a first shallow trench and a predetermined position of a second shallow trench are defined in the patterned mask within the low voltage transistor region. Subsequently, by taking the patterned mask as a mask, the substrate is etched to extend a second trench from a first bottom of the first trench, and a first shallow trench and a second trench are formed within the low voltage transistor region. Next, the patterned mask is removed after forming the second trench, the first shallow trench, and the second shallow trench. Finally, an insulating layer is formed to fill the first trench, the second trench, the first shallow trench and the second shallow trench.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 6 depict a fabrication method of a semiconductor device with a deep trench isolation and a shallow trench isolation according to a preferred embodiment of the present invention, wherein:

FIG. 1 depicts a substrate with a high voltage transistor region and a low-voltage transistor region;

FIG. 2 shows a continuous stage of FIG. 1;

FIG. 3 shows a continuous stage of FIG. 2;

FIG. 4 shows a continuous stage of FIG. 3;

FIG. 5 shows a continuous stage of FIG. 4; and

FIG. 6 shows a continuous stage of FIG. 5.

FIG. 7 depicts a fabricating stage of a high voltage transistor and a fin transistor.

FIG. 8 depicts a modified diagram of a semiconductor device with a deep trench isolation and a shallow trench isolation.

FIG. 9 depicts another modified diagram of a semiconductor device with a deep trench isolation and a shallow trench isolation.

FIG. 10 is an enlarged view of a deep trench isolation according to a preferred embodiment of the present invention

### DETAILED DESCRIPTION

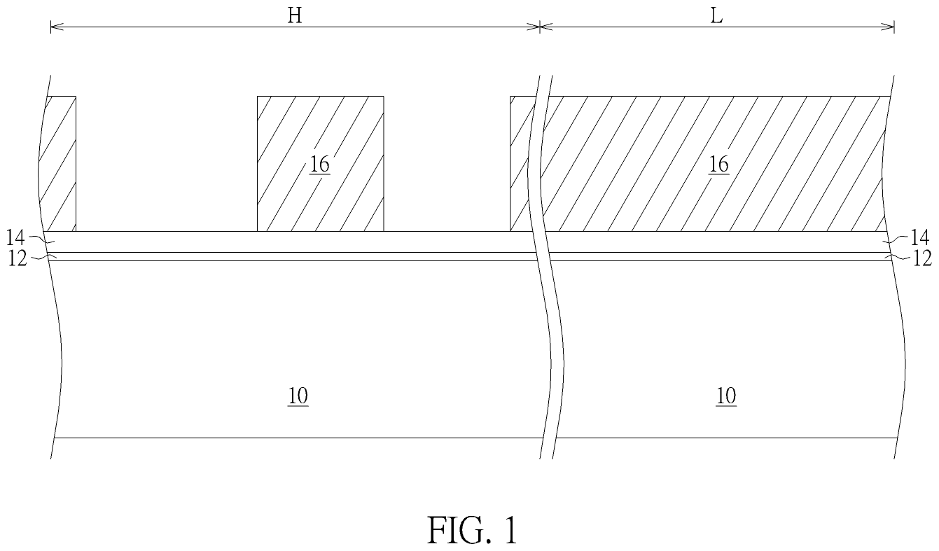

FIG. 1 to FIG. 6 depict a fabrication method of a semiconductor device with a deep trench isolation and a shallow trench isolation according to a preferred embodiment of the present invention.

As shown in FIG. 1, a substrate 10 is provided. The substrate 10 includes a high voltage transistor region H and a low-voltage transistor region L. A pad silicon oxide 12 and a pad silicon nitride 14 cover the high voltage transistor region H and the low voltage transistor region L. The pad silicon oxide 12 is disposed between the pad silicon nitride 14 and the substrate 10. Then, a patterned mask 16 is formed, and the patterned mask 16 completely covers the low voltage transistor region L and part of the high voltage transistor region H is exposed from the patterned mask 16. The patterned mask 16 is preferably a photoresist.

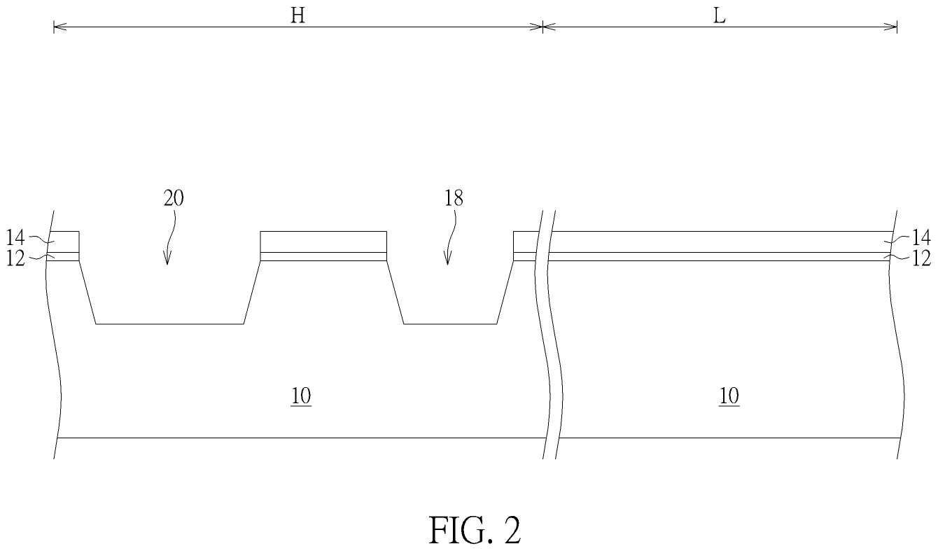

As shown in FIG. 2, by using the patterned mask 16 as a mask, the pad silicon nitride 14, the pad silicon oxide 12, and the substrate 10 in the high voltage transistor region H are etched to form at least one first trench 18 within the pad silicon nitride 14, the pad silicon oxide 12 and the substrate 10. The first trench 18 is located in the high voltage transistor region H. In this embodiment, two first trenches 18/20 are formed as an example, but it is not limited thereto. The widths of the respective openings of the two first trenches 18/20 can be the same or different. Then, the patterned mask 16 is removed.

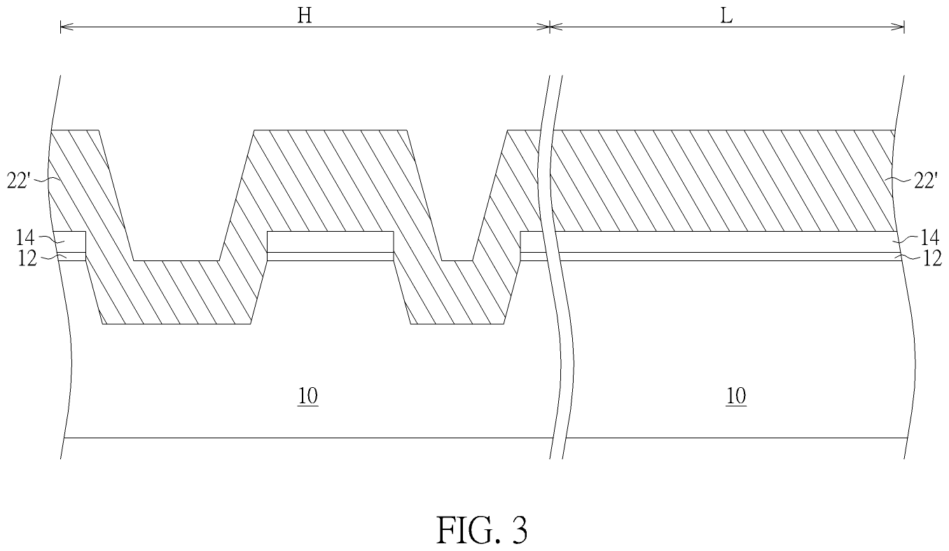

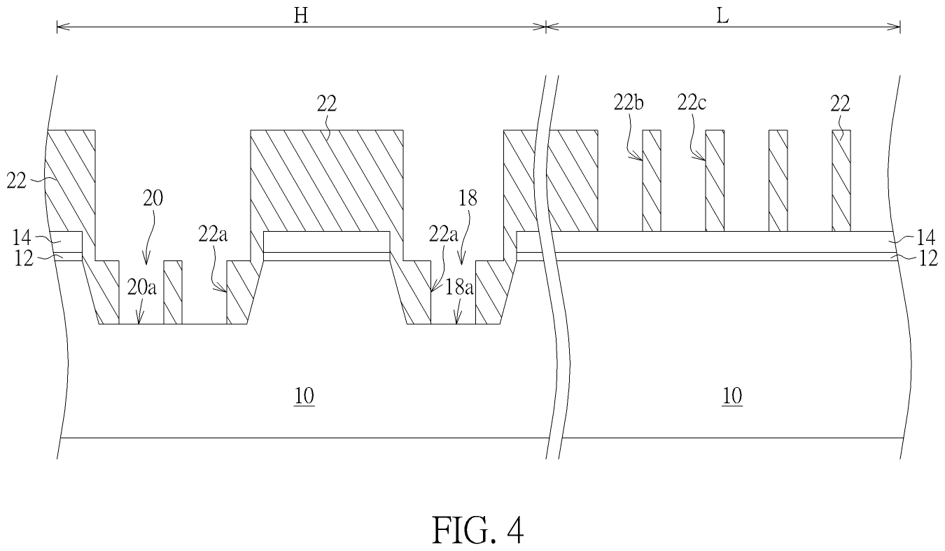

As shown in FIG. 3, a mask 22′ is formed to cover the high voltage transistor region H and the low voltage transistor region L. The mask 22′ fills into the first trenches 18/20. As shown in FIG. 4, the patterned mask 22′ is patterned to form a patterned mask 22. The patterned mask 22 within the high voltage transistor region H defines a predetermined position 22a of the second trench. The patterned mask 22 within the low voltage transistor region L defines a predetermined position 22b of a first shallow trench and a predetermined position 22c of a second shallow trench. The predetermined position 22a of the second trench is located at a bottom 18a of the first trench 18 and at a bottom 20a of the first trench 20. That is, part of the bottom 18a of the first trench 18, the bottom 20a of the first trench 20 and the pad silicon nitride 14 in the low voltage transistor region L are exposed through the patterned mask 22.

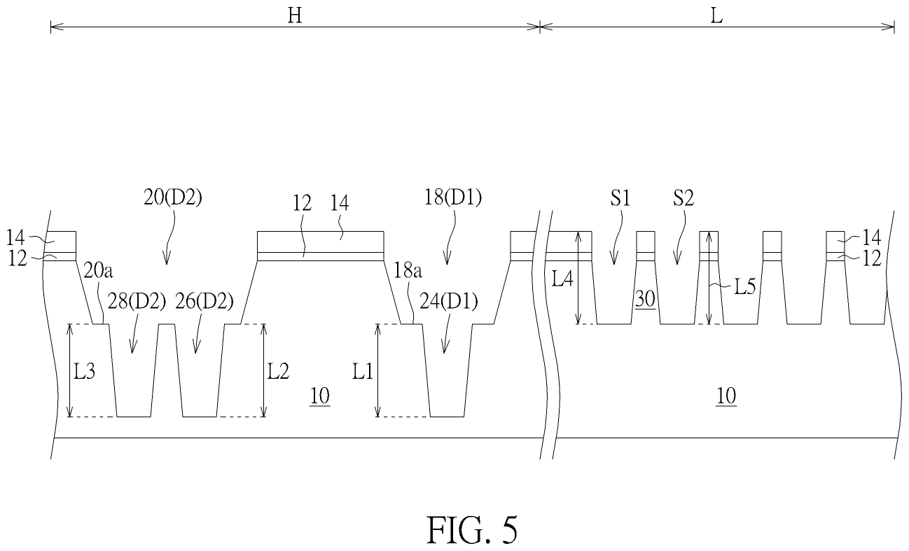

As shown in FIG. 5, by taking the patterned mask 22 as a mask, the substrate 10 is etched to form a second trench 24 extending from the bottom 18a of the first trench 18, and to form a second trench 26 and the second trench 28 extending from the bottom 20a of the first trench 20. Meanwhile, a first shallow trench S1 and a second shallow trench S2 are formed in the pad silicon nitride 14, the pad silicon oxide 12 and the substrate 10 in the low voltage transistor region L. The substrate 10 between the first shallow trench S1 and the second shallow trench S2 is defined as a fin structure 30. Subsequently, the patterned mask 22 is removed. At this point, the first trench 18 and the second trench 24 together form a deep trench D, and the first trench 20, the second trench 26 and the second trench 28 together form a deep trench D2. Because the second trenches 24/26/28, the first shallow trench S1 and the second shallow trench S2 are formed by the same etching step, a length L1 of the second trench 24, a length L2 of the second trench 26, a length L3 of the second trench 28, a length L4 of the first shallow trench S1, and a length L5 of the second shallow trench S2 are all the same. The length L1 of the second trench 24 is defined as a distance from the opening to the bottom of the second trench 24, and the length L2 of the second trench 26 is defined as a distance from the opening to the bottom of the second trench 26, the length L3 of the second trench 28 is defined as a distance from the opening to the bottom of the second trench 28, and the length L4 of the first shallow trench S1 is defined as a distance from the opening to the bottom of the first shallow trench S1. The length L5 of the second shallow trench S2 is defined as a distance from the opening to the bottom of the second shallow trench S2.

In addition, in the embodiment of FIG. 5, a profile of the first shallow trench S1 is the same as a profile of the second shallow trench S2, and a width of the opening of the first shallow trench S1 is the same as a width of the opening of each of the second trenches 24/26/28. The profiles of each of the second trenches 24/26/28 are the same.

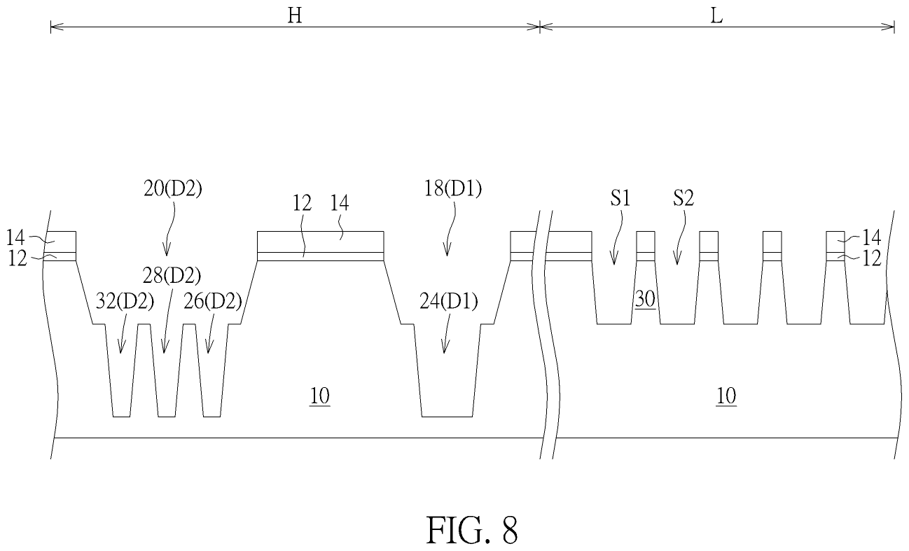

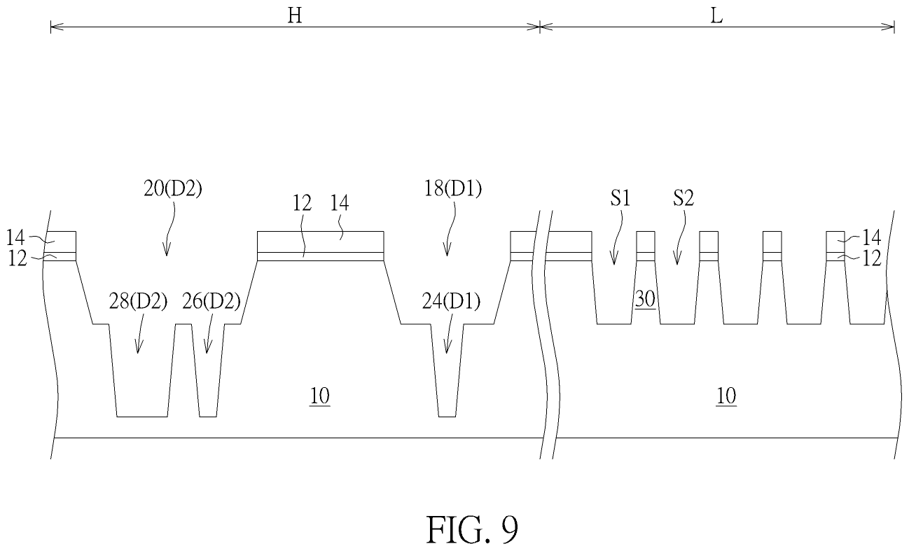

However, a width of the opening of each of the second trenches 24/26/28, the number of second trenches 24/26/28, the number of first shallow trenches S1 and the number of second shallow trenches S2 can be adjusted according to different requirements by only modifying the pattern on the patterned mask 22. For example, as shown in FIG. 8, there can be three second trenches 26/28/32 extending from the bottom 20a of the first trench 20 at the same time. The width of the openings of each of the second trenches 26/28/32 is smaller than the width of the opening of the second trench 24. The width of the opening of the second trench 24 is larger than the width of the opening the first shallow trench S1. As shown in another example in FIG. 9, the width of the opening of the second trench 24 is smaller than the width of the opening of the first shallow trench S1, and the width of the opening of the second trench 26 is smaller than the width of the opening of the second trench 28.

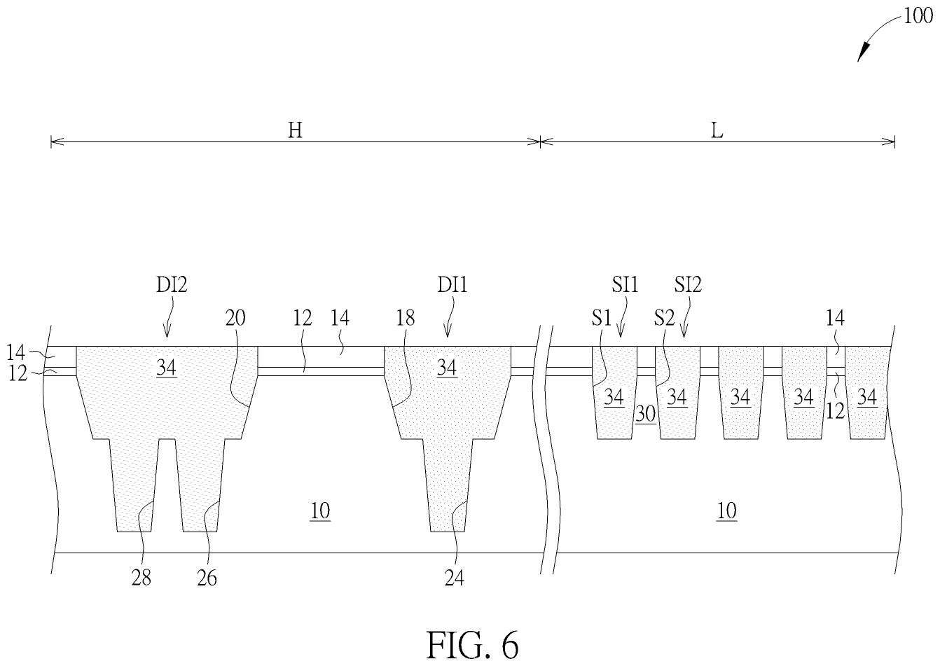

As shown in FIG. 6 which follows the steps in FIG. 5, an insulating layer 34 is formed to fill in the first trenches 18/20, the second trenches 24/26/28, the first shallow trench S1 and the second shallow trench S2. The top surface of insulating layer 34 is aligned with the top surface of pad silicon nitride 14. Now, a semiconductor structure 100 with a deep trench isolation and a shallow trench isolation of the present invention is completed. The first trench 18, the second trench 24 and the insulating layer 34 in the first trench 18 and the second trench 24 form a deep trench isolation DI1. The first trench 20, the second trench 26, the second trench 28 and the insulating layer 34 in the first trench 20, the second trench 26 and the second trench 28 form a deep trench isolation DI2. The first shallow trench S1 and the insulating layer 34 in the first shallow trench S1 form a shallow trench isolation SI1, and the second shallow trench S2 and the insulating layer 34 in the second shallow trench S2 form a shallow trench isolation SI2.

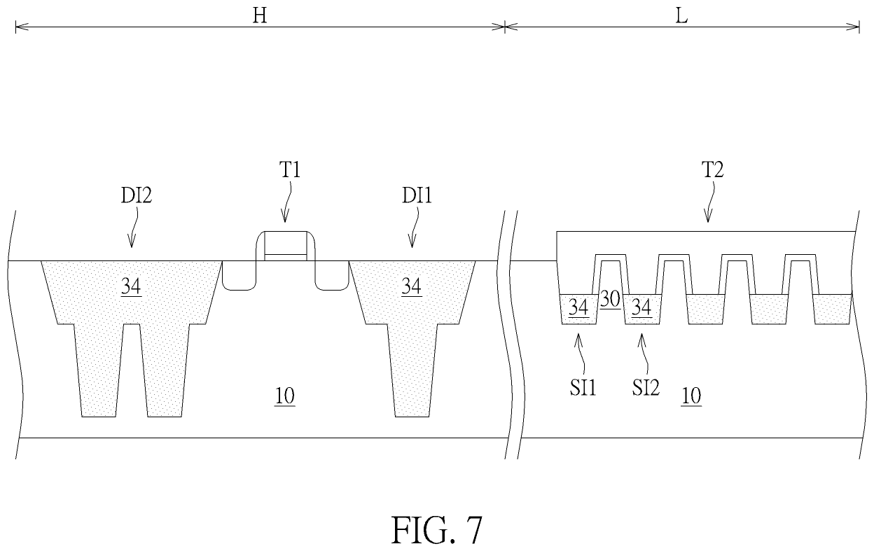

A high voltage transistor and a fin transistor can be fabricated on the semiconductor structure 100 with a deep trench isolation and a shallow trench isolation of the present invention As shown in FIG. 7, the pad silicon nitride 14, the pad silicon oxide 12 and part of the insulating layer 34 are removed, so that the fin structure 30 in the low voltage transistor region L protrudes from the surface of the insulating layer 34 and the insulating layer 34 in the high voltage transistor region H aligned with the top surface of the substrate 10. After that, a high voltage transistor T1 is formed on the substrate 10 between the deep trench isolation DI1 and the deep trench isolation DI2, and a fin transistor T2 is formed on the fin structure 30.

FIG. 6 depicts a semiconductor structure with a deep trench isolation and a shallow trench isolation according to a preferred embodiment of the present invention. Please refer to FIG. 5 and FIG. 6. A semiconductor device 100 with a deep trench isolation and a shallow trench isolation includes a substrate 10. The substrate 10 is divided into a high voltage transistor region H and a low voltage transistor region L. A pad silicon oxide 12 and a pad silicon nitride 14 cover the high voltage transistor region H and the low voltage transistor region L of the substrate 10. A deep trench D1 is disposed within the pad silicon nitride 14, the pad silicon oxide 12 and the substrate 10 within the high voltage region H. The deep trench D1 includes a first trench 18 and a second trench 24. The first trench 18 includes a first bottom 18a. The second trench 24 extends from the first bottom 18a toward a bottom of the substrate 10. A first shallow trench S1 and a second shallow trench S2 disposed in the pad silicon nitride 14, the pad silicon oxide 12 and the substrate 10 within the low voltage transistor region L, wherein the first shallow trench S1 and the second shallow trench S2 define a fin structure 30 on the substrate 10. A length L4 of the first shallow trench S1 is the same as a length L1 of the second trench 24. An insulating layer 34 fills in the first trench 18, the second trench 24, the first shallow trench S1 and the second shallow trench. S2. In addition, the deep trench can also have two second trenches. For example, the deep trench D2 includes a second trench 26 and a second trench 28. Both of the second trench 26 and the second trench 28 extend from the bottom 20a to the bottom of the substrate 10. The second trench 28 is located on one side of the second trench 26, and the insulating layer 34 fills up the second trench 26 and the second trench 28.

Furthermore, the profile of the second trench 24 can be the same as that of the first shallow trench S1 or the profile of the second trench 24 can be different from that of the first shallow trench S1 The profile of the second trench 24 may be the same as or different from those of the second trenches 26/28.

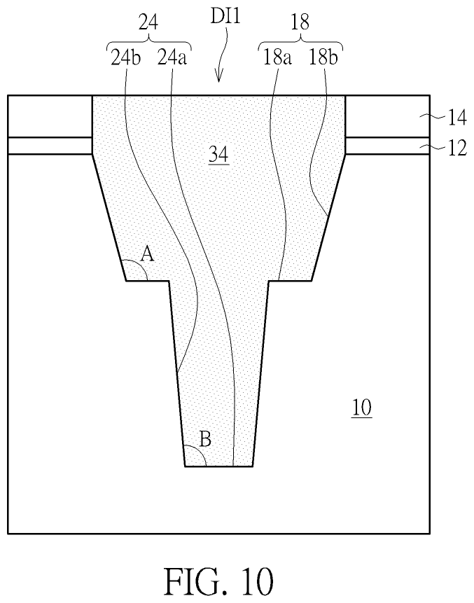

FIG. 10 is an enlarged view of a deep trench isolation according to a preferred embodiment of the present invention, wherein components with the same functions and positions will be designated with the same reference numerals in FIG. 1 to FIG. 6. As shown in FIG. 10, the first trench 18 of the deep trench isolation DI1 includes a first sidewall 18b and a bottom 18a. The inner surface of the first sidewall 18b contacts the insulating layer 34. The second trench 24 includes a bottom 24a and a second sidewall 24b. The inner surface of the second sidewall 24b contacts the insulating layer 34. There is a first angle A between the inner surface of the first sidewall 18b and the bottom 18a, and a second angle B between the inner surface of the second sidewall 24b and the bottom 24a. The first angle A is smaller than 100 degrees, and the second angle B is smaller than 95 degrees. The degrees of the first angle A and the degrees of the second angle B are different, and the first angle A is preferably greater than the second angle B.

The deep trench in the high voltage transistor region of the present invention is composed of the first trench and the second trench. That is, the length of the deep trench is divided into two etching processes, so that the deep trench can be guaranteed to reach the designed depth. In addition, the second trench and the shallow trench located are fabricated by the same etching process; therefore additional steps are not required.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device with a deep trench isolation and a shallow trench isolation, comprising:
a substrate divided into a high voltage transistor region and a low voltage transistor region;
a pad silicon oxide and a pad silicon nitride covering the high voltage transistor region and the low voltage transistor region;
a deep trench disposed within the pad silicon nitride, the pad silicon oxide and the substrate within the high voltage region, wherein the deep trench comprises:
a first trench comprising a first bottom; and
a second trench extending from the first bottom toward a bottom of the substrate;
a first shallow trench and a second shallow trench disposed in the pad silicon nitride, the pad silicon oxide and the substrate within the low voltage transistor region, wherein the first shallow trench and the second shallow trench define a fin structure on the substrate, a length of the first shallow trench is the same as a length of the second trench; and
an insulating layer filling in the first trench, the second trench, the first shallow trench and the second shallow trench.

2. The semiconductor device with a deep trench isolation and a shallow trench isolation of claim 1, wherein the length of the first shallow trench is defined as a distance from an opening of the first shallow trench to a bottom of the first shallow trench, and the length of the second trench is defined as a distance from an opening of the second trench to a bottom of the second trench.

3. The semiconductor device with a deep trench isolation and a shallow trench isolation of claim 1, wherein a width of the opening of the first shallow trench is the same as a width of the opening of the second trench.

4. The semiconductor device with a deep trench isolation and a shallow trench isolation of claim 1, wherein a width of the opening of the first shallow trench is different from a width of the opening of the second trench.

5. The semiconductor device with a deep trench isolation and a shallow trench isolation of claim 1, wherein a profile of the first shallow trench is the same as a profile of the second shallow trench.

6. The semiconductor device with a deep trench isolation and a shallow trench isolation of claim 1, wherein the first trench further comprises a first sidewall, an inner surface of the first sidewall contacts the insulating layer, the second trench further comprises a second bottom and a second sidewall, an inner surface of the second sidewall contacts the insulating layer, there is a first angle between the inner surface of the first sidewall and the first bottom, a second angle between the inner surface of the second sidewall and the second bottom, the first angle is smaller than 100 degrees, and the second angle is smaller than 95 degrees.

7. The semiconductor device with a deep trench isolation and a shallow trench isolation of claim 6, wherein a degree of the first angle is different from a degree of the second angle.

8. The semiconductor device with a deep trench isolation and a shallow trench isolation of claim 1, wherein the deep trench further comprises a third trench extending from the first bottom to the bottom of the substrate, the insulating layer fills up the third trench, and the third trench is disposed at one side of the second trench.

9. The semiconductor device with a deep trench isolation and a shallow trench isolation of claim 8, wherein a profile of the third trench is the same as a profile of the second trench.

10. The semiconductor device with a deep trench isolation and a shallow trench isolation of claim 8, wherein a profile of the third trench is different from a profile of the second trench.

11. An integrated fabricating method of a deep trench isolation in a high voltage transistor region and a shallow trench isolation in a low voltage transistor region, comprising:
providing a substrate comprising a high voltage transistor region and a low voltage transistor region, a pad silicon nitride and a pad of silicon oxide covering the high voltage transistor region and the low voltage transistor region;
etching the pad silicon nitride, the pad silicon oxide and the substrate to form a first trench in the pad silicon nitride, the pad silicon oxide and the substrate within the high voltage transistor region;
forming a patterned mask covering the high voltage transistor region and the low voltage transistor region, wherein the patterned mask fills the first trench, and a predetermined position of the second trench is defined in the patterned mask within the high voltage transistor region and a predetermined position of a first shallow trench and a predetermined position of a second shallow trench are defined in the patterned mask within the low voltage transistor region;
by taking the patterned mask as a mask, etching the substrate to extend a second trench from a first bottom of the first trench, and forming a first shallow trench and a second trench within the low voltage transistor region;
removing the patterned mask after forming the second trench, the first shallow trench, and the second shallow trench; and
forming an insulating layer to fill the first trench, the second trench, the first shallow trench and the second shallow trench.

12. The integrated fabricating method of a deep trench isolation in a high voltage transistor region and a shallow trench isolation in a low voltage transistor region of claim 11, wherein a length of the first shallow trench is defined as a distance from an opening of the first shallow trench to a bottom of the first shallow trench, a length of the second trench is defined as a distance from an opening of the second trench to a bottom of the second trench, and the length of the first shallow trench is the same as the length of the second trench.

13. The integrated fabricating method of a deep trench isolation in a high voltage transistor region and a shallow trench isolation in a low voltage transistor region of claim 11, wherein a width of the opening of the first shallow trench is the same as a width of the opening of the second trench.

14. The integrated fabricating method of a deep trench isolation in a high voltage transistor region and a shallow trench isolation in a low voltage transistor region of claim 11, wherein a width of the opening of the first shallow trench is different from a width of the opening of the second trench.

15. The integrated fabricating method of a deep trench isolation in a high voltage transistor region and a shallow trench isolation in a low voltage transistor region of claim 11, wherein the first trench further comprises a first sidewall, an inner surface of the first sidewall contacts the insulating layer, the second trench further comprises a second bottom and a second sidewall, an inner surface of the second sidewall contacts the insulating layer, there is a first angle between the inner surface of the first sidewall and the first bottom, a second angle between the inner surface of the second sidewall and the second bottom, the first angle is smaller than 100 degrees, and the second angle is smaller than 95 degrees.

16. The integrated fabricating method of a deep trench isolation in a high voltage transistor region and a shallow trench isolation in a low voltage transistor region of claim 15, wherein a degree of the first angle is different from a degree of the second angle.

17. The integrated fabricating method of a deep trench isolation in a high voltage transistor region and a shallow trench isolation in a low voltage transistor region of claim 11, further comprising by taking the patterned mask as the mask, etching the substrate to form a third trench extending from the first bottom, the insulating layer fills up the third trench, and the third trench is disposed at one side of the second trench.

18. The integrated fabricating method of a deep trench isolation in a high voltage transistor region and a shallow trench isolation in a low voltage transistor region of claim 17, wherein a profile of the third trench is the same as a profile of the second trench.

19. The integrated fabricating method of a deep trench isolation in a high voltage transistor region and a shallow trench isolation in a low voltage transistor region of claim 17, wherein a profile of the third trench is different from a profile of the second trench.

20. The integrated fabricating method of a deep trench isolation in a high voltage transistor region and a shallow trench isolation in a low voltage transistor region of claim 11, wherein the first shallow trench and the second shallow trench define a fin structure on the substrate.
